(19) United States
(12) Patent Application Publication
(10) Pub. No.: US 2006/0268976 A1
(43) Pub. Date: Nov. 30, 2006

(54) METHOD AND APPARATUS FOR DETERMINING CHANNEL QUALITY AND PERFORMING ADAPTIVE MODULATION CODING WITHIN A MULTI CARRIER COMMUNICATION SYSTEM

(75) Inventors: Kevin Baum, Rolling Meadows, IL (US); Yufei Blankenship, Streamwood, IL (US); Brian Classon, Palatine, IL (US); Philippe Sartori, Algonquin, IL (US)

Correspondence Address: MOTOROLA, INC., 1303 EAST ALGONQUIN ROAD, IL01/3RD, SCHAUMBURG, IL, 60196, US

(73) Assignee: MOTOROLA, INC., Schaumburg, IL (US)

(21) Appl. No.: 11/279,401

(22) Filed: Apr. 12, 2006

Related U.S. Application Data
(60) Provisional application No. 60/677,228, filed on May 3, 2005.

(51) Int. Cl. H03K 9/04

(52) U.S. Cl. 375/239

(57) ABSTRACT

For short-term link adaptation, a base station obtains instantaneous information for the channel condition seen by a subscriber station. For long-term link adaptation, the base station obtains distribution information for the channel conditions seen by the subscriber station over a period of time. Adaptive modulation and coding is done at the base station based on the distribution information.

### RELATED APPLICATIONS

This application claims priority to U.S. Provisional Application No. 60/677,228, filed May 3, 2005.

### FIELD OF THE INVENTION

The present invention relates generally to communication systems, and in particular, to a method and apparatus for determining channel quality and performing adaptive modulation/coding within a multi-carrier communication system.

### BACKGROUND OF THE INVENTION

Multi-carrier modulation and Orthogonal Frequency Division Multiplexing (OFDM) in particular, are attractive technologies for broadband high data-rate communications due to their robustness against long delay spread and lower complexity when compared to single carrier systems. In addition to multi-carrier modulations, Adaptive Modulation/Coding (AMC) is also a fundamental technique for wireless broadband communications. With AMC, the modulation and coding scheme (MCS) of a transmitted data stream for a particular receiver is changed to predominantly match a current received signal quality (at the receiver) for the particular frame being transmitted. The received signal quality is determined by the channel quality. (The terms “received signal quality” and “channel quality” can be referred to interchangeably). Thus, streams with high quality are typically assigned higher order modulations and/or higher channel coding rates with the modulation order and/or the code rate decreasing as quality decreases. For those receivers experiencing high quality, modulation schemes such as 16-QAM, 64-QAM or 256-QAM are utilized, while for those experiencing low quality, modulation schemes such as BPSK or QPSK are utilized. Multiple coding rates may be available for each modulation scheme to provide finer AMC granularity, to enable a closer match between the quality and the transmitted signal characteristics (e.g., R=¼, ½, and ¾ for QPSK; R=½ and R=⅔ for 16-QAM, etc.). AMC attempts to achieve highest signaling rate (product of modulation order and code rate) while keep the frame error rate at or below a target. AMC typically yields higher system throughputs and higher data rates than other conventional link adaptation techniques such as power control.

Link adaptation in OFDM systems involves selecting the modulation and coding rate combination, sometimes called the modulation/coding scheme (MCS), which is appropriate for the current channel conditions. Some OFDM (or Discrete Multi-Tone (DMT)) systems (such as wire-line DSL) separately treat contiguous subsets of sub-carriers for power allocation, coding, or modulation. If the subsets are selected with a small enough granularity, frequency-selective (FS) link adaptation can be performed where the link adaptation on a subset may be analogous to an AWGN channel. However, most OFDM systems take a frequency-diverse (FD) approach and perform interleaving of a codeword over many or all of the OFDM sub-carriers. Since the SNR of each sub-carrier can be different due to frequency selective fading, the appropriate MCS is not easily determined. For example, choosing the MCS based on the average SNR over the sub-carriers often gives inaccurate results, leading to either reduced throughput or additional retransmissions (latency).

One technique that has been found to provide accurate results for MCS selection when the instantaneous SINR is known for each sub-carrier is the exponential ESM (EESM) method. This method computes a single effective SNR, denoted SNR_{eff}, over the OFDM sub-carriers as:

$${SNR}_{eff} = EESM ( \{ {γ}_{1} , … , {γ}_{N} \} , β ) = - β \cdot ln ( \frac{1}{N} {\sum }_{i = 1}^{N} exp ( - \frac{{γ}_{i}}{β} ) ) , \qquad ( 1 )$$

where N is the number of sub-carriers, γᵢ is the received symbol SNR at the i-th sub-carrier, and β is a calibration parameter that may be different for each MCS. SNR_{eff} is the equivalent static channel SNR, such that the given MCS achieves the same frame error rate (FER) in the static channel with SNR_{eff} as in the frequency selective channel with {γ₁, . . . , γ_{N}} benefit of the EESM method is that a single, empirically determined β value is valid for a wide range of FS channels. The typical accuracy for the wide range of channels is <0.5 dB, which is evaluated for a target FER of 1%.

The link adaptor may be at a subscriber station (SS, also known as mobile station, subscriber station, user equipment, etc.), where the SS sends a request for the best data rate or MCS. The link adaptor may be at the base station (BS), where the SS sends the set of SNR_{eff} to the BS.

Several problems exist when applying EESM under realistic channel conditions. One problem occurs when EESM is used for short term link adaptation. (Short term link adaptation, as used here, means that the channel frequency response does not change significantly between the time it is measured and the time when a transmission is made using an MCS selected based on that measurement.) To reduce the amount of feedback, it is normally incorrectly assumed that:
(1) The existing calibration of the relationship between SNR_{eff} and β is accurate for current transmission.
(2) The realization of the power delay profile of the channel does not change significantly from frame-to-frame due to Doppler.
(3) When the channel SNR changes, the relationship between SNR_{eff} (dB) and β (dB) can be parallel shifted from the SNR_{eff} (dB) and β relationship of a previous channel SNR.

Therefore, a need exists for method and apparatus for improving the accuracy of short-term link adaptation while maintaining low feedback.

Secondly, the EESM method is currently only applicable for short-term link adaptation. The EESM method does not provide an accurate MCS selection for the case of long term link adaptation, i.e., when the channel response changes significantly between the measurement and the next transmission (e.g., due to Rayleigh fading with moderate to large Doppler frequencies). Since many SS's in a mobile system can be moving too fast for short term link adaptation, there is a need for methods that enable the BS to make a more accurate determination of an appropriate MCS selection for long term link adaptation. Therefore, a need exists for a method and apparatus for accurately determining channel quality and performing adaptive modulation/coding within a multi-carrier communication system that accommodates for long-term link adaptation.

### BRIEF DESCRIPTION OF THE DRAWINGS

FIG. 1 is a block diagram of a multi-carrier communication system that utilizes adaptive modulation and coding.

FIG. 2 illustrates the multiple carriers utilized in an OFDM communication system.

FIG. 3 illustrates channel quality as a function of frequency.

FIG. 4 illustrates the effect of scaling and of shifting an SNR_{ef} versus β_{dB} curve.

FIG. 5 illustrates the curves of Eₛ/N₀=3 dB and 10 dB from FIG. 4

FIG. 6 illustrates how three points can be used to approximate a cdf.

FIG. 7 shows a Ricean approximation for a Ped B channel.

FIG. 8 is a block diagram of multi-carrier base station and subscriber station utilizing AMC.

FIG. 9 is a flow chart showing operation of the transmitter of FIG. 8.

FIG. 10 is a flow chart showing operation of subscriber station of FIG. 8.

FIG. 11 is a block diagram of a multi-carrier base station and subscriber station utilizing AMC.

FIG. 12 is a flow chart showing operation of the transmitter of FIG. 11.

FIG. 13 is a flow chart showing operation of subscriber station of FIG. 11

### DETAILED DESCRIPTION OF THE DRAWINGS

To address the above-mentioned needs a method and apparatus for determining channel quality and performing adaptive modulation and coding in a multi-carrier communication system is provided herein. The modulation and coding scheme may change on a frame-by-frame basis in order to track the channel quality variations that occur in mobile communication systems, or may be performed more infrequently such as for example, once per super-frame. In accordance with the preferred embodiment of the present invention for short-term link adaptation, the BS obtains instantaneous information for the channel condition seen by the SS. For long-term link adaptation, the base station (BS) obtains distribution information for the channel conditions seen by the subscriber station (SS) over a period of time. The period of time could be specified as a specific number of frames, a minimum number of frames, etc. or in units of actual time. The amount of time is preferably large enough for the channel to experience several fades due to Rayleigh fading, but short enough that the longer term channel characteristics (e.g. path loss, power delay profile) are not changing significantly. The distribution information can be related to a probability density function (pdf), a cumulative distribution function (cdf), etc., and the distribution information can be for one or more parameters of interest for MCS selection, such as SNR_{eff}, SNR_{band}, bit error rate (BER), FER, and so forth. Here SNR_{band} is preferably the mean signal to noise-plus-interference ratio over a set of sub-carriers for a particular received OFDM symbol, such as all occupied sub-carriers or a representative set of sub-carriers.

The distribution information is preferably in a compact form to reduce feedback overhead form the SS to the BS. Examples of a compact form include one or more sample values from the distribution (e.g., the 5% point of the cdf), parameters for an analytical model of the distribution (e.g., parameters of a Ricean distribution that provide a good fit to the sample distribution), etc. Also, partial information on the distribution might be sent back such as the lower half of the cdf (up to 0.5), or the pdf up to the median value.

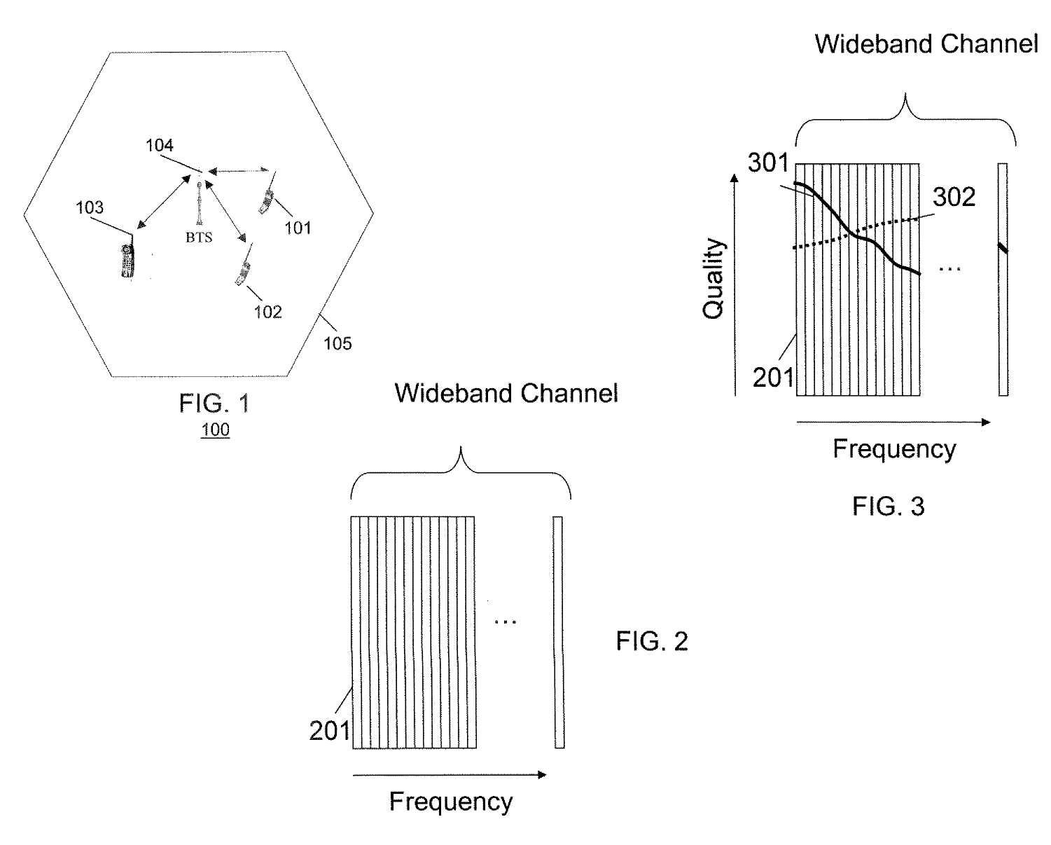

Turning now to the drawings, wherein like numerals designate like components, FIG. 1 is a block diagram of multi-carrier communication system 100. Communication system 100 comprises a plurality of cells 105 (only one shown) each having a base station 104 in communication with a plurality of subscriber stations 101-103. Subscriber stations 101-103 may also be known as subscriber stations, mobile stations, or user equipment. In the preferred embodiment of the present invention, communication system 100 utilizes an Orthogonal Frequency Division Multiplexed (OFDM) over-the-air protocol utilizing Adaptive Modulation and Coding (AMC). The architecture may also include the use of multi-carrier spreading techniques such as multi-carrier CDMA (MC-CDMA), multi-carrier direct sequence CDMA (MC-DS-CDMA), Interleaved Frequency Domain Multiple Access (IFDMA), Orthogonal Frequency and Code Division Multiplexing (OFCDM) with one or two dimensional spreading, or may be also combined with simpler time and/or frequency division multiplexing/multiple access techniques.

As one of ordinary skill in the art will recognize, during operation of an OFDM system, multiple sub-carriers (e.g., 768 sub-carriers) are utilized to transmit wideband data. This is illustrated in FIG. 2. As shown in FIG. 2 the wideband channel is divided into many narrow frequency bands, or sub-carriers 201, with data being transmitted in parallel on sub-carriers 201. At the transmission time, a transmitter is typically assigned a plurality of sub-carriers.

In addition to OFDM, communication system 100 utilizes AMC. With AMC, the modulation and coding format is changed to predominantly match a current received signal quality of the sub-carriers at the receiver. The received signal quality can be obtained on a frame by frame basis, or on a longer time scale such as a superframe by superframe basis, where a superframe is composed of a plurality of frames, or on an as-needed basis. In a first embodiment, the same modulation and coding scheme is assigned for predominantly all the sub-carriers used to transmit to a particular subscriber station, and channel coding is done in frequency domain, across the sub-carriers. In alternate embodiments, the modulation and coding scheme may be assigned on a per-sub-carrier basis or a per-group of sub-carrier basis. The modulation and coding scheme may change on a frame-by-frame basis in order to track the channel quality variations that occur in mobile communication systems or may change on a longer timescale and may be based on averaged signal quality indicators. Streams with high quality are assigned higher order modulations and/or higher channel coding rates with the modulation order and/or the code rate decreasing as quality decreases. For those sub-carriers experiencing high quality, modulation schemes such as 16-QAM, 64-QAM or 256-QAM are utilized, while for those experiencing low quality, modulation schemes such as BPSK or QPSK are utilized.

In the preferred embodiment of the present invention multiple coding rates are available for each modulation scheme to provide finer AMC granularity, and to enable a closer match between the channel quality and the transmitted signal characteristics (e.g., coding rate R=¼, ½, and ¾ for QPSK; R=½ and R=⅔ for 16-QAM, etc.). Note that AMC can be performed in the time dimension (e.g., updating the modulation/coding every Nₜ OFDM symbol periods) or in the frequency dimension (e.g., updating the modulation/coding every N_{sc} sub-carriers) or a combination of both. In the preferred embodiment, AMC is performed in the time dimension for each subscriber station.

FIG. 3 illustrates how the quality of the signal can change based on frequency. More particularly, FIG. 3 shows how quality 301 of a signal may vary over frequency, or the channel bandwidth. In this example, quality 301 degrades as the frequency increases. It should be noted however that a different signal with the same average Signal-to-Noise or Signal-to-(Noise-plus-Interference) Ratio (SNR) as signal 301 might have a very different channel quality profile. For instance, quality 302 has the same average SNR as 301, but presents much smoother variations than quality 301.

As discussed above, in order to achieve high system throughput, the system may use short-term or long-term link adaptation. For short-term link adaptation, the base station obtains the instantaneous channel quality information from the SS. More particularly, the SS compiles channel quality information over a plurality of sub-carriers and sends it to BS.

For long-term link adaptation, the base station obtains distribution information for the channel conditions seen by the subscriber station over a period of time. More particularly, channel quality information for a plurality of sub-carriers is determined by the subscriber station over a period of time and information about the channel quality over time is sent back to the base station. The period of time could be specified as a specific number of frames, a minimum number of frames, etc. or in units of actual time. The amount of time is preferably large enough for the channel to experience several fades due to Rayleigh fading, but short enough that the longer term channel characteristics (e.g. path loss, power delay profile) are not changing significantly. Channel quality information may comprise SNR information, effective SNR information, FER or BER information, etc., or a combination of one or more of these indicators.

The channel-quality information and its time-varying nature are used to determine distribution information, such as a cumulative distribution function (cdf) of the channel-quality information, a probability density function (pdf) of the channel-quality information, partial cdf or pdf information (such as one or more sample points), etc. This distribution information is preferably determined by the subscriber station. Three techniques are given below for reporting distribution information (e.g., transmitted from a subscriber station to a base station) and utilizing the distribution information (e.g., at the base station) for one or more parameters of interest for MCS selection. However, prior to describing the techniques for reporting distribution information and utilizing the distribution information for one or more parameters of interest for MCS selection, the following text and equations are provided to set the necessary background for utilization of the preferred embodiment of the present invention.

SNR_{eff} is the effective signal to noise-plus-interference ratio calculated utilizing an EESM method or a variation of it.

SNR_{band} is the mean signal to noise-plus-interference ratio over a set of sub-carriers for a received OFDM symbol, such as all occupied sub-carriers or a representative set of sub-carriers. Note that SNR_{band} can change significantly from frame to frame at high vehicle speeds. Note that SNR_{band} can be calculated as

$${SNR}_{band} = \frac{1}{N} {\sum }_{i = 1}^{N} {γ}_{i} .$$

Also note that while the examples given here assume that the γᵢ associated with SNR_{eff} and SNR_{band} are from different sub-carriers, in general they can be associated with the sub-carriers and symbol periods over which an FEC codeword is interleaved (e.g., interleaving over a combination of sub-carriers and OFDM symbol periods). Depending on the transmission scheme, SNR_{band} may be the average over a plurality of sub-carriers and a plurality of symbol periods, and the symbol periods may or may not be adjacent to each other.
EESM Link Adaptation

For reduced-feedback EESM link adaptation, a model (best fit equation) of the SNR_{eff} (dB) vs. β (dB) curve is determined at the SS and sent back to the BS. The model and model parameters may be, for example, a linear model, piecewise linear model, quadratic model, cubic model, etc. This model is determined for a particular channel realization (or alternatively a representative channel realization or an average channel realization) having a particular SNR_{eff} at a reference value of β. Curve/best fit parameters are sent from the SS to the BS.

After the curve parameters are sent back to the BS, the SS then sends SNR_{eff} values to the BS, such as on a frame by frame basis. The reference β value is known by the SS and BS, either a priori through signaling or implicit calculation, or through including it along with the SNR_{eff}. It is intended that the model curve parameters should not need to be updated as long as the channel power-delay profile does not change significantly. Therefore, while the SNR_{eff} may need to be reported on a frame-by-frame basis for short term link adaptation, the underlying curve parameters should remain valid for many frames because the model is typically appropriate for different channel realizations from the same power delay profile, and changes in the power delay profile will occur much more slowly than changes in the instantaneous complex channel gain coefficients due to Doppler.

With a simple curve shifting approach, for each received SNR_{eff} at the BS, it is assumed that the SNR_{eff} vs. β curve for the current SNR_{eff} value is obtained by a simple shift of the curve that was recently sent to the BS. For example, if SS sends back an SNR_{eff} value of 10 dB in the current frame (for a reference β value that was predetermined) and the curve parameters that the SS previously sent to the BS had an SNR_{eff} of 5 dB (for the same value of β), then the SNR_{eff} vs. β curve for the current frame would be obtained by adding 5 dB to all of the SNR_{eff} values of the original SNR_{eff} (dB) vs. β (dB) curve that the SS previously sent to the BS. In other words, the model curve parameters are assumed to be unchanged regardless of channel SNR change.

However, the simple shifting approach described above leads to some inaccuracy in the SNR_{eff} vs. β curve for the current frame. The method may be sufficiently accurate in the vicinity of the β value for which the SS sent back the current SNR_{eff} value, but may be inaccurate for other values of β. The accuracy of the shifted modeled curve is improved in the present invention as follows.

In the following it is shown that the change in received SNR can be modeled exactly given the same channel selectivity. The BS has the original SNR_{eff} vs. β curve, and it can analytically compute a family of new curves, each assuming a different SNR_{eff} value at the reference β value.

Recall the definition of EESM,

$${SNR}_{eff} = EESM ( \{ {γ}_{1} , … , {γ}_{N} \} , β ) = - β \cdot ln ( \frac{1}{N} {\sum }_{i = 1}^{N} exp ( - \frac{{γ}_{i}}{β} ) ) .$$

Consider the SNR_{eff} of the same channel selectivity but different average SNR, i.e., the per-sub-carrier SNR vector is scaled to {αγ₁, . . . , αγ_{N}}, α>0, in linear domain,

$$\begin{matrix}EESM ( \{ a {γ}_{1} , … , a {γ}_{N} \} , β ) = - β \cdot ln ( \frac{1}{N} {\sum }_{i = 1}^{N} exp ( - \frac{a {γ}_{i}}{β} ) ) \\ = a [ - \frac{β}{a} \cdot ln ( \frac{1}{N} {\sum }_{i = 1}^{N} exp ( - \frac{{γ}_{i}}{β / a} ) ) ] \\ = a \times EESM ( \{ {γ}_{1} , … , {γ}_{N} \} , β / a )\end{matrix} \qquad ( 2 )$$

When SNR_{eff}, β and a are expressed in dB, (2) becomes
EESM_{dB}({αγ₁, . . . , αγ_{N}},β_{dB})=α_{dB}+EESM_{dB}({γ₁, . . . , γ_{N}}β_{dB}−α_{dB}), (3)
where α_{dB}=10 log₁₀ α, and EESM_{dB} is expressed as a function of β_{dB} and β_{dB}=10 log₁₀ β.

If the curve of EESM_{dB}({γ₁, . . . , γ_{N}},β_{dB}) vs β_{dB} is known, then equation (3) can be used to obtain the curve of EESM_{dB}({αγ₁, . . . , αγ_{N}},β_{dB}) for any value of SNR due to scale α.

Note that to use equation (3) to generate curves for β≠1, not only the EESM_{dB}({γ₁, . . . , γ_{N}},β_{dB}) vs β_{dB} relationship needs to be available in the β_{dB} region corresponding to the available MCS set, but also for any β_{dB}-α_{dB} value needed. For example, curve fitting parameters are obtained based on β_{dB} range of [0, 15], which corresponds to the available MCS set. To be able to use equation (3) the EESM_{dB}({γ₁, . . . , γ_{N}},β_{dB}) vs β_{dB} relationship is needed in the range of [−α_{dB}, 15] if α_{dB}>0, and [0, 15−α_{dB}] α_{dB}<0. Depending on the range of β_{dB}, quadratic approximation may not be sufficient, and an additional cubic parameter may be needed to accurately model the EESM_{dB}({γ₁, . . . , γ_{N}},β_{dB}) vs β_{dB} relationship in a wide β_{dB} range. Alternatively, a quadratic or even linear approximation may be enough if only a small range of β_{dB} is needed, for example, when the power fluctuation is small and only a small range of MCS need to be considered for link adaptation.

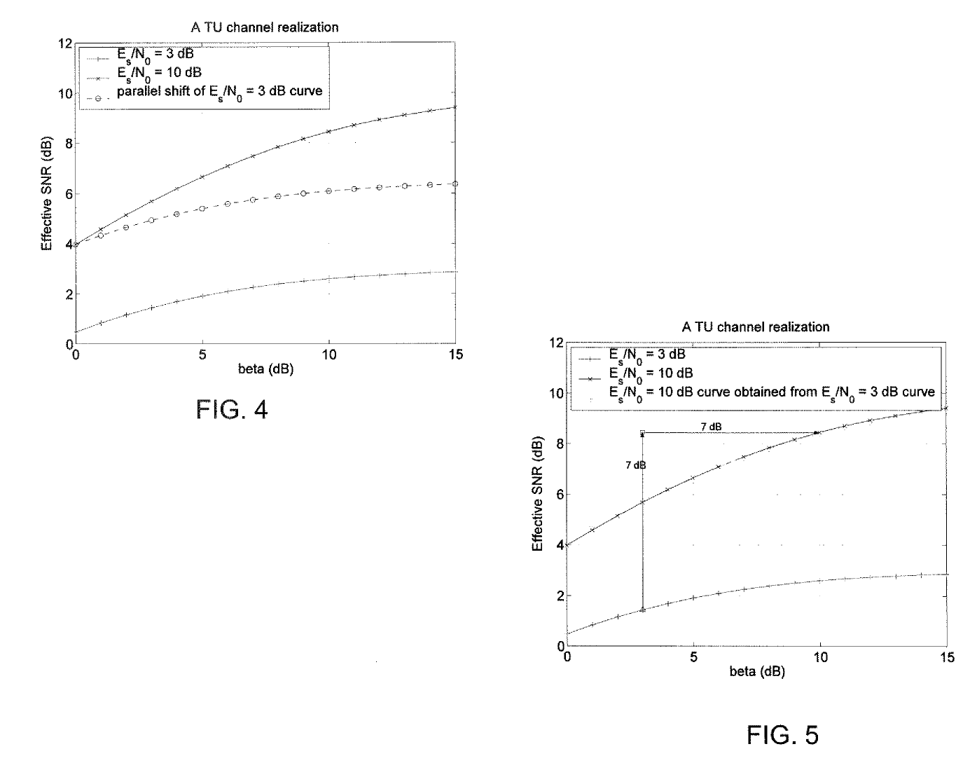

FIG. 4 shows the effect of scaling and of shifting an SNR_{ef} versus β_{dB} curve. In FIG. 4, a GSM Typical Urban (TU) channel realization is used as an example to show the error of using the simple curve shift approach to obtain the EESM_{dB}({αγ₁, . . . , αγ_{N}},β_{dB}) vs β_{dB} curve from a EESM_{dB}({γ₁, . . . , γ_{N}},β_{dB}) vs β_{dB}. In FIG. 4, the EESM_{dB} curve is shown for channel Eₛ/N₀=3 dB and 10 dB. A parallel shift of the Eₛ/N₀=3 dB curve (i.e., the simple curve shifting method) is also shown. Comparing the parallel shifted curve and the Eₛ/N₀=10 dB curve, it is clear that if the parallel shifted Eₛ/N₀=3 dB curve is used to approximate the Eₛ/N₀=10 dB curve, then significant error would occur.

In FIG. 5, the curves of Eₛ/N₀=3 dB and 10 dB from FIG. 4 are included. A third curve is obtained using the relationship in equation (3) together with a polynomial approximation of the Eₛ/N₀=3 dB curve. This shows that relationship in equation (3) can be used to obtain an exact curve of EESM_{dB}({αγ₁, . . . , αγ_{N}},β_{dB}) vs β_{dB} curve from a EESM_{dB}({γ₁, . . . , γ_{N}},β_{dB}) vs β_{dB} curve.

The described method can be used to provide a more accurate determination of how much power boosting is needed. The same approach can also be used to compute how much the transmit power can be reduced while still providing an adequate frame error rate (FER) to a particular SS. The improved accuracy for power boosting or power reduction calculations enables the BS to allocate its available power budget more efficiently across the multiple SSs being scheduled in the same OFDM symbol. The power allocation process in the downlink is also known as downlink power allocation or downlink power control.

Note that although the preferred embodiment discusses the model where both SNR_{eff} and β are in dB scale, the model can also be characterized with one or both of SNR_{eff} and β in linear scale.

Enhancement of EESM Such that a SS can Feed Back Regular SNR Reports Rather than EESM SNR_{eff} Reports.

In this method, a SS first transmits an SNR_{eff} vs. β model to the BS (e.g., linear or quadratic approximation to the SNR_{eff} vs. β curve, where SNR_{eff} and β can be in either linear or dB scale SNR_{eff,dB}, β_{dB}). In addition, a reference SNR_{band} value, denoted as SNR_{ref}, at which the curve parameters are obtained, may be needed for the model curve. There are two ways to provide the SNR_{ref}. The first method is to have the SS transmit the SNR_{ref} value for the curve along with the curve parameters. A disadvantage of this approach is that it requires additional overhead. The second method is to have the SS compute the curve for a predetermined SNR_{ref} value (e.g., 10 dB) that is known to both the BS and SS ahead of time. Then the BS knows that the curve parameters are valid for the predetermined SNR_{ref} value. For this method, the SS will scale each of the actual per-sub-carrier SNR by the same value q such that after scaling SNR_{band}=SNR_{ref}, and will then determine the curve parameters to send to the BS. Then, in normal operation between curve parameter updates, the SS can send back the normal SNR_{band} without any scaling.

After the BS has the information for the SNR_{eff} vs. β curve at the reference SNR_{ref} value, the SS can send back normal SNR_{band} without any scaling instead of SNR_{eff} in normal operation (e.g., on a frame by frame basis between curve parameter updates) and the BS can re-compute the SNR_{eff} vs. β curve for each received SNR_{band} from the SS by using the relationship based on equation (3):
SNR_{eff}(SNR_{band},β)=SNR_{band}/SNR_{ref}×SNR_{eff}(SNR_{ref},β), where β′=β×SNR_{ref}/SNR_{band}
CDF Points for SNR_{band}

In a first embodiment of the present invention a cumulative distribution function is obtained for a signal-to-noise ratio for the frequency band of sub-carriers. For this embodiment, the SS stores an average SNR for the frequency band (SNR_{band}) values for a preferably large number of channel snapshots, such as for the last 100 frames. In other words, the SS monitors the SNR for each sub-carrier and computes an average for the whole frequency band (SNR_{band}). SNR_{band} is monitored over a time period with a plurality of SNR_{band} values being obtained over time. Then the SS sorts the values for SNR_{band} into ascending order, and after some simple calculations determines an estimate of the distribution (e.g., cdf) of the SNR_{band} values. The SS then sends one or more points from the sample-based cdf back to the BS. For example, there may be a predetermined rule that the SS will send back three specific points from the cdf, such as the 5% point (e.g., the SNR_{band} value for which 5% of the channel snapshots had an equal or lower value), the 20% point, and the 50% point.

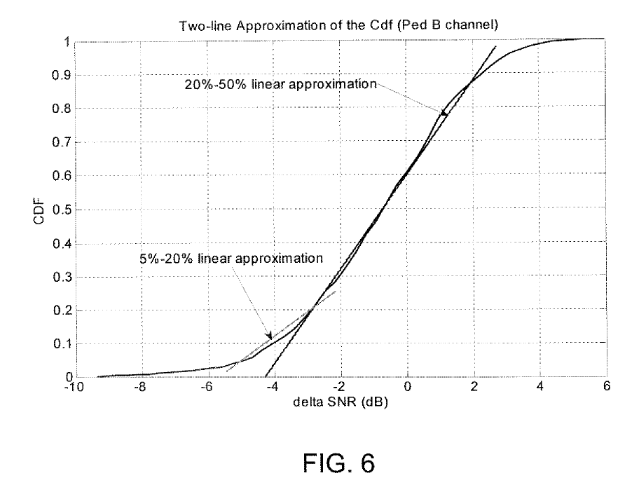

FIG. 6 depicts how these three points can be used to approximate the cdf in the case of a Ped B channel. As it can be seen, this bi-linear approximation is excellent for the cdf values between 0.02 (2%) and 0.7 (70%). Typically, the cdf curve is not needed in its entirety so that only a portion of the cdf (such as the cdf for the cdf values between 0.05 and 0.5) or its approximation needs to be fed back.

The BS can use the information to help the process of selecting an MCS level for a subsequent transmission to the SS. For example, if the BS knows that the channel to the SS is basically flat faded, the BS knows that it can use static FER vs. SNR curves to determine an appropriate MCS level: by choosing an MCS level having a negligible FER at the SNR_{band} value of the 5% point reported by the SS, the BS knows that there is approximately a 5% likelihood that a transmission using that MCS level would have an error (for an MCS level having a non-negligible FER at the X % point, the probability of a frame error can be predicted as (1−(1−FER_{ref})(1=0.01X)), where FER_{ref} is the static FER at the SNR corresponding to the X % cdf point). This type of information can be used to help the BS decide how aggressive to be in MCS selection and to anticipate how much of the channel resources may be needed for retransmissions in subsequent frames.

The BS can also interpolate between the points provided by the SS to provide a finer granularity in the distribution information at the BS, and can also extrapolate to provide approximated distribution information beyond the range reported by the SS. Simulation results indicate that the BS can reconstruct a fairly accurate approximation of the distribution in the region of interest (e.g., 1% to 50% range) by having the SS send back two or preferably three points from the distribution in that range. The BS can then use a simple two-line-segments approximation (for the three point case) by “connecting the dots” and extrapolating.

Note that the description above assumes that the SS measures the cdf over a period of time and then sends some cdf information back to the BS. An alternative approach is for the SS to send back SNR reports frequently over a period of time (e.g., every frame or every few frames) so that the BS has the information necessary to create the cdf directly. However, this latter method requires more feedback than the SS-based method.

Up until this point, the method as described so far is accurate for a flat fading channel, but will suffer from reduced accuracy in frequency selective channels. Therefore, an EESM enhancement is used to make the cdf technique applicable to any channel type by occasionally sending back the SNR_{eff} vs. β curve. Basically, when the BS has an SNR_{eff} vs. β curve the BS can convert any point on the SNR_{band} cdf to a point on a cdf of SNR_{eff}. If the X % cdf point is known for SNR_{band}, one can determine the X % point for SNR_{eff} at a particular value of β as follows:
SNR_{eff,X%}(SNR_{band,X%},β)=SNR_{band,X%}/SNR_{ref}×SNR_{eff}(SNR_{ref},β′),

where β′=β·SNR_{ref}/SNR_{band,X%}

where SNR_{eff,X%} is the X % point of the SNR_{eff} cdf for the specified value of β, and where SNR_{band,X%}, is the X % point of the SNR_{band} cdf.

Based on this method, the BS can first construct an approximation to the SNR_{band} cdf curve in the region of interest (e.g., based on points fed back from the SS and curve fitting or line segments) and can then translate as many points from that cdf as desired into the cdf points for SNR_{eff}, and this can be done for each β of interest (e.g., the β for each MCS) to provide the information needed to assist in MCS selection. In this case, SNR_{eff} is used as the SNR value in the static FER curves to estimate the performance or probability of error for a particular MCS level.

An alternate embodiment of this method works entirely in the SNR_{eff} domain rather than converting from SNR_{band} cdf values to SNR_{eff} cdf values. In this alternate embodiment, the SS stores SNR_{eff} values for a particular β value over a period of time and determines a cdf for the SNR_{eff} values at that value of β. Then, the SS sends samples from this cdf to the BS, and the BS can work directly with the SNR_{eff} cdf. Besides the cdf samples, the SS also needs to send SNR_{eff} vs. β curve information, such as the curve parameters. The BS also needs to know what value of β is associated with the cdf information being sent by the SS (i.e., the β used by the SS when it determines the cdf). There are two methods for providing this information. In the first method, the SS sends the β value for the cdf in addition to the cdf samples. In the second method, the β value is specified and known to both the BS and SS ahead of time, such that there is no need for the SS to send a β value to the BS. Once the BS has the cdf samples, the SNR_{eff} vs. β curve information, and the β value for the cdf, it can compute cdf samples for other values of β and use these to assist in the MCS selection process. Determining the X % cdf point for an arbitrary β value is possible based on the following method. First, let the original cdf be available for a known value of β denoted as β_{ref}. Next, an SNR_{eff} vs. β curve which passes through the X % SNR_{eff} point on the original cdf is determined (this curve can be derived from SNR_{eff} vs. β curve information sent earlier by the SS, using equation (3) to shift the curve appropriately). This new SNR_{eff} vs. β curve is denoted as curve_X, Finally, the X % cdf point for an arbitrary β value is obtained by taking the SNR_{eff} value from curve_X at the β value of interest. This procedure can be repeated for several cdf points.

Model Based Distribution Approximation

In a model-based distribution approximation, instead of sending back samples from a distribution function as proposed in the previous section, an analytical model is assumed and is used to characterize the SNR distribution. In the second embodiment, the particular model being used is known to the BS and SS, and the SS determines a set of parameters to characterize the model and sends those parameters back to the BS. Thus, the SS monitors the SNR for each sub-carrier and computes an average for the whole frequency band (SNR_{band}). SNR_{band} is monitored over a time period with a plurality of SNR_{band} values being obtained over time. Then the SS attempts to fit the plurality of SNR_{band} values to a specific function. Certain function parameters are then fed back to the base station.

In a first embodiment, a Ricean model for the SNR pdf is utilized. Another potentially useful model is a Gaussian distribution of the SNR pdf. If multiple models are found to be useful for a particular system, the SS can send a model specifier in addition to the model parameters (e.g., if model index=1, the SS is using a Ricean model, or if model index=2, the SS is using a Gaussian model).

The BS can compute an approximation of the SNR_{band} cdf (this time based on the model assumption and model parameters received from the SS). This cdf can then be used in the same ways as were described above.

The SS could perform the modeling, parameter computations, and feedback of the model parameters for SNR_{eff} rather than SNR_{band}, but simulations indicate that a better model fit can usually be obtained for SNR_{band} than SNR_{eff}. If the modeling is done for SNR_{eff}, note that equation (3) will need to be used to obtain cdf values for different values of f.

Ricean model: Assume that the mean and standard deviation of SNR_{band} are μ and ν. The distribution of SNR_{band} can be approximated by a non-central chi square distribution Y:

$${p}_{Y} ( y ) = \frac{1}{2 {σ}^{2}} {ⅇ}^{- ( {s}^{2} + y ) / 2 {σ}^{2}} {I}_{o} ( \sqrt{y} \frac{s}{{σ}^{2}} )$$

where Iₒ is the modified Bessel function of the first kind. s and σ are obtained from μ and ν by the following equations:

$$σ = \sqrt{\frac{μ - \sqrt{{μ}^{2} - {v}^{2}}}{2}}$$

$$and$$

$$s = \sqrt{\frac{{v}^{2}}{4 {σ}^{2}} - {σ}^{2}}$$

The Ricean distribution for the amplitude is obtained by the change of variable Z=\sqrt{Y}.

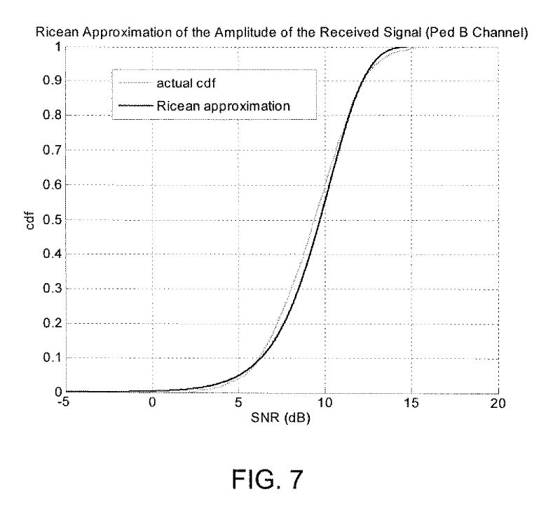

FIG. 7 shows a Ricean approximation for a Ped B channel. The Ricean approximation is very good for a Ped B channel at a mean SNR value of 10 dB. Since the Ricean distribution is completely specified by only two parameters, it has minimal feedback requirements. Note that the SS can either send the mean and standard deviation of the SNR_{band} distribution or can compute s and σ, the parameters determining the non-central chi square distribution. Alternatively, the SS can send the parameters characterizing the Ricean distribution.

Generally, the shape of the current SNR_{eff} vs. β can be used to determine information about the relative frequency selectivity of the channel. For example, in flat fading, the curve becomes a flat line. In highly frequency selective channels, the curve slope becomes large. The larger the slope of the curve, the less SNR variation will occur from frame to frame. The shape of the curve, such as the local slope at one or more values of β, or parameters of the curve (e.g., quadratic and linear coefficients) can be used assist in the link adaptation process. In one example, if the SNR_{eff} vs. β curve is close to a horizontal line (with β on the horizontal axis), then the channel has low frequency diversity and the distribution can be approximated as flat Rayleigh fading. If the curve shape indicates a large amount of channel frequency diversity, then the distribution will have a relatively steeper slope, indicating potentially lower SNR variation between frames. Similarly, the shape of the cdf of SNR_{band} can serve as an indicator of the channel condition.

A base station can then base the MCS selection on the shape of the SNR_{eff} vs. β curve or the cdf of SNR_{band}. More particularly, knowing the shape of the cdf allows the BS to more accurately determine an MCS level for the SS. For example, if the cdf is basically a vertical line and the SS is receiving a real-time service with no ARQ, then the BS knows that the SNR will not change significantly between frames and the MCS selection does not need to include any significant amount of fading margin. As the slope of the curve decreases, then the BS can calculate an appropriate amount of fading margin (or alternatively power boosting) to include in the MCS selection.

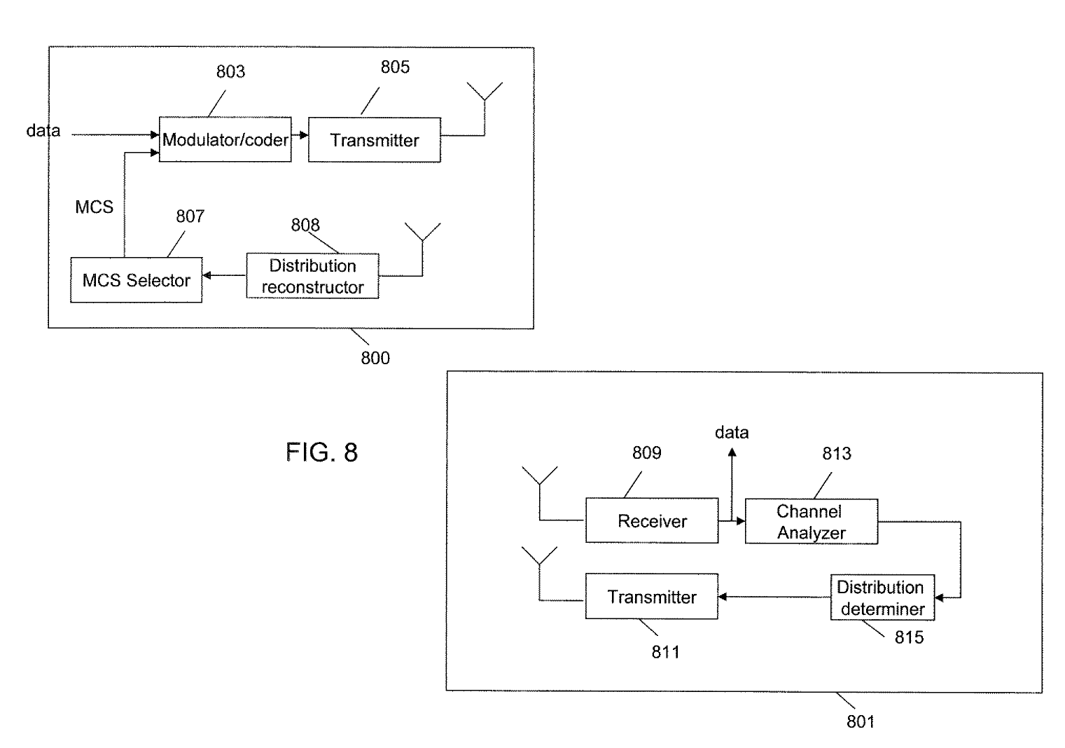

FIG. 8 is a block diagram of multi-carrier base station 800 and subscriber station 801 utilizing AMC. As discussed above, base station 800 receives data that is to be transmitted to a receiver and effectively transmits the data by coding it across multiple sub-carriers. A single modulation and coding scheme is used for a set of sub-carriers (e.g., the sub-carriers being used to transmit to a particular SS) and is dependent upon the channel quality of predominantly all occupied sub-carriers. Thus, data enters the transmitter and is effectively modulated and coded via adaptive modulator and coder 803. After proper modulation and coding, the data stream is transmitted (via transmitter 805) on a plurality of sub-carriers.

Subscriber station 801 comprises channel analyzer 813, receiving the over-the-air signal from receiver 809. Channel analyzer 813 serves to determine the SNR values for each of a plurality of sub-carriers or sets of sub-carriers and derive wide-band SNR metrics (e.g., SNR_{band}, or alternatively SNR_{eff}) over time. In the first embodiment of the present invention the metric (e.g., SNR_{band}, or alternatively SNR_{eff}) values are rank ordered and a distribution function is determined (by distribution determiner 815) based on the rank ordering. Distribution determiner 815 generates the signal quality distribution of SNR_{band} (or alternatively SNR_{eff}) based on inputs from channel analyzer 813.

In the first embodiment of the present invention, distribution determiner 815 utilizes transmitter 811 to transmit back to base station 800 one or more specific points of the distribution function. For example, distribution determiner 815 may determine the 5% point (e.g., the SNR_{band} value for which 5% of the channel snapshots had an equal or lower value), the 20% point, and the 50% point, and transmit these values to base station 800. Although SNR_{band} has been described, distribution determiner can work on either SNR_{band} or SNR_{eff} values for a reference β value.

In the second embodiment of the present invention, distribution determiner 815 fits a curve to the distribution derived from the ranked SNR_{band} values. Depending on the curve being fit to the SNR_{band} values, specific variables defining the curve will be transmitted (via transmitter 811) back to base station 800. For example, with the approximation of Ricean distribution, the SS can send back s and σ, the parameters determining the non-central chi square distribution approximating the SNR_{band} distribution. Again, while described for SNR_{band}, the embodiment may alternatively use SNR_{eff} values for a reference β value.

In the preferred embodiment of the present invention modulator/coder 803 at the BS 800 utilizes a modulation and coding scheme that is dependent upon the channel quality of the channel bandwidth. Depending on whether the first or the second embodiments are being utilized, distribution reconstructor 808 will either receive parameters defining a best-fit curve to the SNR-over-time distribution, or will receive various values of a cdf curve. If more than one distribution point is provided, reconstructor 808 may reconstruct a portion of the distribution of the channel quality indicator (if only one point of the distribution is received, the reconstruction defaults to providing the same value as was received). Reconstructor 808 reconstructs the distribution based on either the values of the cdf curve or the parameters defining the best-fit curve. The distribution reconstructor 808 may utilize SNR_{X}, the SNR such that for X % of the channel instances, the actual SNR is less than or equal to SNR_{X}. For example, SNR₁₀ is the SNR value corresponding to a cdf value of 0.1.

After receiving the distribution information from the distribution reconstructor, MCS selector then computes a predicted channel quality (γ_{eff}) for the number of possible modulation and coding schemes available. MCS selector 807 then chooses the best modulation and coding scheme for the desired point. In particular the base station typically chooses the MCS yielding the highest possible throughput, where the selected MCS usually has an expected FER lower than the target FER. In addition, the shape of the reconstructed distribution (e.g., slope in a region of interest) may be used to assist in the MCS selection process. For example, a steep cdf slope indicates that the MCS selection is likely to be accurate on a short-term basis, so that if an MCS is selected based on a 10% FER point, it is 90% likely to be correctly received on the next transmission even at high Doppler. On the other hand, as the shape of the distribution approaches that of flat fading in a high Doppler situation, an MCS selected based on a 10% FER point is 90% likely to be received on average over the fading, rather than on a short-term basis. As a result, the MCS selection for the case of a steep slope can be considered more accurate on a short-term basis, allowing for a more aggressive MCS selection (e.g., less fade margin).

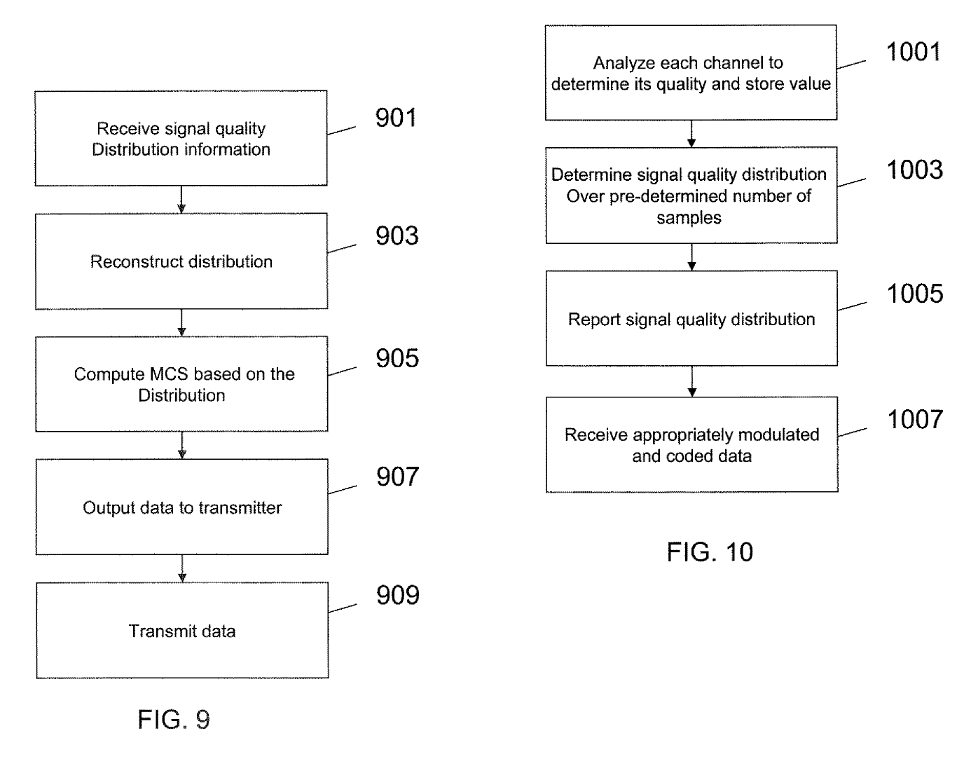

FIG. 9 is a flow chart showing operation of the base station 800 of FIG. 8. The logic flow begins at step 901 where the reconstructor 808 receives a signal quality distribution information. This distribution information can comprise one or more points of the cdf representing the distribution or may comprise the parameters representing the distribution in the case of the Ricean distribution or other model-based distributions. At step 903, distribution reconstructor 808 reconstructs the distribution of the channel quality indicator from the distribution information and passes this to MCS selector 807. For example, reconstructor 808 may compute CQ_{X}, the effective channel quality observed on at least X % of the samples (in other words, the probability of observing a SNR_{eff} less than what is computed is X %).

At step 905 selector 807 determines an MCS based on the distribution generated by reconstructor 808. More particularly, in a first embodiment, selector 807 computes the expected FER for all candidate MCS schemes for CQ_{X}. In some cases, the FER may not need to be computed. In that case, a threshold comparison may be made to the 1% or other FER of interest from a required SNR_{eff} table/tables. The candidate MCS scheme may be all or a subset of the available MCS schemes. Alternatively, interpolation techniques can be used to compute the expected FER for some MCSs. The MCS chosen at step 905 is based on the expected FER values. In particular, the MCS that has the highest possible throughput with an expected FER lower than a target value (typically 10⁻¹) is chosen. At step 907 the data stream is input into modulator and coder 803, being appropriately modulated and coded with the MCS, and the data stream is transmitted via transmitter 805 at step 909.

As discussed, the shape of the reconstructed distribution (e.g., slope in a region of interest) may be used by MCS selector 807 to assist in the MCS selection process. For example, a steep cdf slope indicates that the MCS selection is likely to be accurate on a short-term basis, so that if an MCS is selected based on a 10% FER point, it is 90% likely to be correctly received on the next transmission even at high Doppler. On the other hand, as the shape of the distribution approaches that of flat fading in a high Doppler situation, an MCS selected based on a 10% FER point is 90% likely to be received on average over the fading, rather than on a short-term basis. As a result, the MCS selection for the case of a steep slope can be considered more accurate on a short-term basis, allowing for a more aggressive MCS selection (e.g., less fade margin).

FIG. 10 is a flow chart showing operation of subscriber station 801. The logic flow begins at step 1001 where each utilized sub-channel is analyzed by analyzer 813 to determine its quality. The channel quality obtained for each sample is stored in analyzer 813. At step 1003 a distribution for the signal quality is determined by determiner 815 and parameters needed to represent at least a portion of this distribution are computed. At step 1005 the parameters needed to represent at least a portion of the distribution are reported back to base station 800 to aid in determining an appropriate MCS. Finally, at step 1007 data is received modulated and coded with the appropriate MCS.

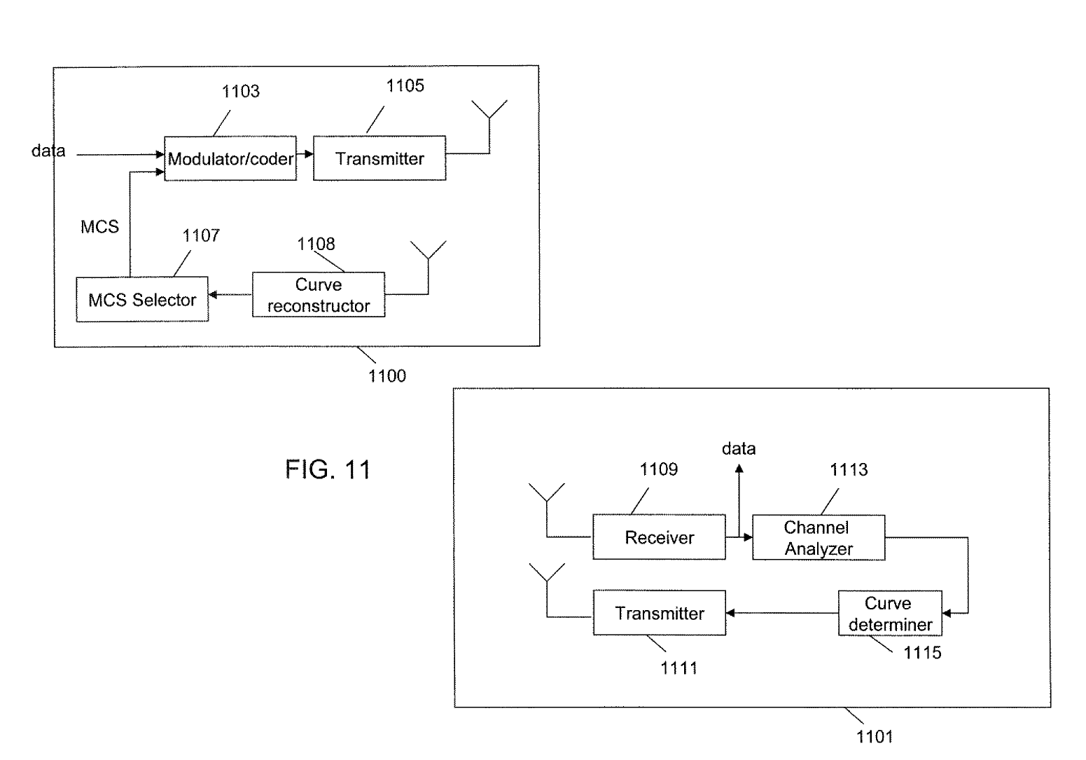

As discussed above, transmitter 800 and receiver 801 can be operated utilizing short-term, or fast AMC. In such a scenario, no distribution of SNR will be needed and distribution determiner 815 and distribution reconstructor 808 will be replaced by a curve determiner and a curve reconstructor, respectively. This is shown in FIG. 11.

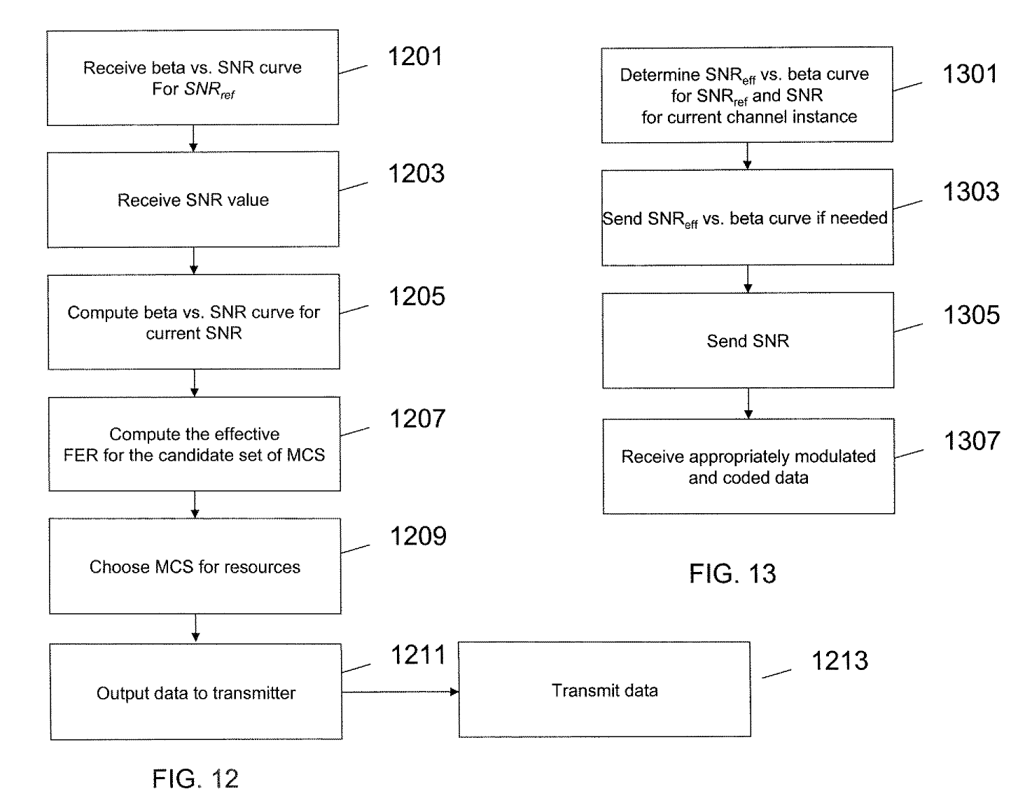

FIG. 12 is a flow chart showing operation of transmitter 1100 of FIG. 11 for fast AMC. The logic flow begins at step 1201 where the curve reconstructor 1108 receives an SNR_{eff} vs. β curve obtained for a reference SNR value, SNR_{ref}, using equation (3). At step 1203, curve reconstructor 1108 receives an SNR value from SS 1101 indicating a current SNR. At step 1205, MCS selector 1107 computes the SNR_{eff} vs. β curve based on the reference curve sent at step 1201 and the SNR value sent at step 1203 using equation (3). At step 1207 selector 1107 computes the SNR_{eff}, which relates to FER, for a plurality candidate MCS schemes by figuring SNR_{eff} for the β value associated to a given MCS using the SNR_{eff} vs. β curve computed at step 1205. By substituting the appropriate β value for each MCS, a set of SNR_{eff} can be obtained for all MCS available. The link adaptor is then able to accurately select the best MCS for the {γ₁, . . . , γ_{N}} channel based on the set of SNR_{eff}, which is the highest MCS that the static FER corresponding to its SNR_{eff} is lower than the target FER. The candidate MCS scheme may be all or a subset of the available MCS schemes. Alternatively, interpolation techniques can be used to compute the expected FER for some MCSs. The MCS utilized is chosen at step 1209 based on the expected FER values In particular, the MCS that has the highest possible throughput with an expected FER lower than a target value (typically 10⁻¹) is typically chosen. At step 1211 the data stream is input into transmitter 405, being appropriately modulated and coded, and the data stream is transmitted at step 1213.

FIG. 13 is a flow chart showing operation of receiver 1101 for fast AMC. The logic flow begins at step 1301 where the SNR_{eff} vs. β curve is determined by curve determiner 1115 along with the current SNR for the current channel instance and a reference SNR value. This is accomplished by analyzing SNR values provided by channel analyzer 1113. At step 1303 the SNR_{eff} vs. β curve for the current channel is compared by determiner 1115 with the previously sent SNR_{eff} vs. β curve that is currently used by transmitter 800. If the curve for the current channel is different enough than the previously sent curve (e.g., if the least square error is greater than 2 dB over a pre-determined range of β values), the parameters representing the SNR_{eff} vs. β curve are reported to the transmitter. At step 1305, the SNR is reported to transmitter 1100 via transmitter 1111. Finally, at step 1307 data is received modulated and coded with the appropriate MCS.

While the invention has been particularly shown and described with reference to a particular embodiment, it will be understood by those skilled in the art that various changes in form and details may be made therein without departing from the spirit and scope of the invention. For example, the invention was described for OFDM, but could be applied to any system using multi-carrier modulations. Additionally, MCS selection could be used only over a fraction of the data streams available, the other data streams using known MCS selection techniques (for instance based on the average SNR value). In another example, SNR_{band} may be the average of a set of received symbol SNR, which may include the effect of code combining in hybrid ARQ context. It is intended that such changes come within the scope of the following claims.

1. A method for adaptive modulation and coding, the method comprising the steps of:
receiving distribution information for a channel quality of a wideband channel over time;
determining a distribution of channel quality for the wideband channel based on the received distribution information;
determining a modulation and coding scheme based on the distribution; and
modulating and coding data based on the modulation and coding scheme.

2. The method of claim 1 wherein the channel quality comprises at least one of SNR, SNR_{eff}, SNR_{band}, BER, FER, SINR.

3. The method of claim 1 wherein the step of receiving distribution information comprises the step of receiving the distribution information from a subscriber station.

4. The method of claim 1 wherein the step of receiving distribution information comprises the step of receiving one or more points of a cumulative distribution function.

5. The method of claim 1 wherein the step of receiving distribution information comprises the step of receiving one or more sample values of a distribution.

6. The method of claim 4 wherein the step of receiving one or more points of a distribution function comprises the step of receiving one or more points of a probability density function.

7. The method of claim 1 wherein the step of receiving distribution information comprises the step of receiving one or more parameters for a predetermined distribution function.

8. The method of claim 7 wherein the predetermined distribution function is one of a predetermined cumulative distribution function and a predetermined probability density function.

9. The method of claim 7 wherein the step of determining the distribution of channel quality for the wideband channel based on the received distribution information comprises determining the distribution of channel quality based on the predetermined distribution function and the one or more received parameters for the predetermined distribution function.

10. The method of claim 7 wherein the step of receiving one or more parameters for a predetermined distribution function comprises the step of receiving parameters for a Ricean distribution function.

11. A method comprising the steps of:
receiving a wideband signal;
computing signal quality values for the signal over time;
determining a distribution for the signal quality values for the signal over time;
and providing distribution information to a base station for use in adaptive modulating and coding.

12. The method of claim 11 wherein the step of providing distribution information to the base station comprises the steps of:
computing a best-fit function to the distribution for the signal quality values for the signal over time; and
providing parameters to the base station regarding the best-fit function.

13. The method of claim 12 wherein the best-fit function is based on a predetermined function, and wherein the step of computing a best-fit function to the signal quality values comprises computing parameters for the predetermined function, and wherein the step of providing parameters to the base station regarding the best-fit function comprises providing the computed parameters for the predetermined function.

14. The method of claim 11 wherein the signal quality comprises at least one of SNR, SNR_{eff}, SNR_{band}, BER, FER, SINR.

15. The method of claim 12 wherein the best-fit function is based on one of a plurality of predetermined functions, and wherein the step of computing a best-fit function to the signal quality values comprises computing parameters for a selected one of the predetermined functions, and wherein the step of providing parameters to the base station regarding the best-fit function comprises providing the computed parameters for the selected one of the predetermined functions.

16. The method of claim 11 wherein the step of providing distribution information to the base station comprises the steps of:
computing a probability density function of the signal quality values; and
providing one or more data points to the base station regarding the probability density function.

17. A method for transmitting data, the method comprising the steps of:
obtaining instantaneous channel quality information;
determining a first modulation and coding scheme based on the instantaneous channel quality information;
transmitting data based on the first modulation and coding scheme;
obtaining distribution information for a channel quality of a wideband channel over time;
determining a distribution of channel quality for the wideband channel based on the distribution information;
determining a second modulation and coding scheme based on the distribution; and
transmitting data based on the second modulation and coding scheme.
